(19) United States
(12) Patent Application Publication
(10) Pub. No.: US 2006/0118974 A1
(43) Pub. Date: Jun. 8, 2006

(54) Structure provided on an overlay region, overlay mark having the structure, and method of forming the overlay mark

(76) Inventors: Dae-Joung Kim, Suwon-si (KR); Dae-Youp Lee, Gunpo-si (KR); Young-Koog Han, Seoul (KR)

Correspondence Address: HARNESS, DICKEY & PIERCE, P.L.C., P.O. BOX 8910, RESTON, VA, 20195, US

(21) Appl. No.: 11/290,473

(22) Filed: Dec. 1, 2005

(30) Foreign Application Priority Data
Dec. 2, 2004 (KR) 2004-100200

(51) Int. Cl. H01L 23/544

(52) U.S. Cl. 257/797

(57) ABSTRACT

A structure, which may be provided on an overlay region for an overlay mark, may include a first pattern that may project from a peripheral portion of the overlay region that may be defined on a scribe lane of a substrate. A second pattern may project from a central portion of the overlay region.

### PRIORITY STATEMENT

This application claims benefit of priority under 35 USC §119 to Korean Patent Application No. 2004-100200, filed on Dec. 2, 2004, the contents of which are herein incorporated by reference in its entirety.

### BACKGROUND

1. Field of the Invention

Example, non-limiting embodiments of the present invention relate generally to a structure that may protect an overlay region where an overlay mark may be formed, an overlay mark having the structure, and a method of forming the overlay mark. More particularly, example, non-limiting embodiments of the present invention relate to a structure that may be provided on a scribe lane of a semiconductor substrate where an overlay mark may be formed, an overlay mark having the structure, and a method of forming the overlay mark.

2. Description of the Related Art

A semiconductor device may be highly integrated, so that intervals between patterns on a semiconductor substrate may be narrowed. The patterns may be formed on the semiconductor substrate by techniques that may involve a deposition process and a patterning process, for example.

When the pattern forming techniques are carried out, it may be desirable to align a lower pattern that may formed in a preceding process (for example) with an upper pattern that may formed in a following process (for example). To recognize the alignment of the upper pattern and the lower pattern, an overlay mark may be provided on a scribe lane of the semiconductor substrate.

FIG. 1 is a plan view a conventional overlay mark that may be provided on a scribe lane of a semiconductor substrate, and FIG. 2 is a cross sectional view taken along a line 11-11′ in FIG. 1.

Referring to FIGS. 1 and 2, a conventional overlay mark 10 may include an outer mark 11 and an inner mark 12. The outer mark 11 may define an interior region. The inner mark 12 may be arranged on the interior region of the outer mark 11. The outer mark 11 may correspond to four trenches that are provided in a surface portion of a scribe lane L of a semiconductor substrate S. Each of the trenches may have a rectangular shape. The inner mark 12 may correspond to a photoresist pattern provided on the scribe lane L.

The outer mark 11 may be formed by a preceding process for forming a lower pattern. The inner mark 12 may be formed by a following process for forming an upper pattern. Intervals between the outer mark 11 and the inner mark 12 may be measured to determine an alignment between the upper pattern and the lower pattern.

The scribe lane L may be divided into a plurality of regions (“overlay regions”) where respective overlay marks 10 may be formed. Only first, second, third and fourth overlay regions R1, R2, R3 and R4 are shown in FIG. 1, although any number of overlay regions may be provided. When a process for manufacturing a semiconductor device is performed, the conventional overlay marks 10 may be sequentially formed in each of the first, second, third and fourth overlay regions R1, R2, R3 and R4, respectively.

The processes for manufacturing the semiconductor device may include a chemical mechanical polishing (“CMP”) process that may be implemented to planarize a layer 20 that may be provided on the semiconductor substrate S. The CMP process may involve providing slurry on the layer 20. A surface of the layer 20 may be planarized using a polishing pad.

As shown in FIG. 1, overlay marks 10 may be provided in the first and the second overlay regions R1 and R2, respectively, while overlay marks 10 may not be provided in the third and the fourth overlay regions R3 and R4. When the CMP process is performed on the layer 20, the polishing pad may contact the inner mark 12 in the first overlay region R1. The polishing pad may also contact the layer 20 in the third overlay region R3. The polishing pad may contact the inner mark 12 in the first overlay region R1, and the layer 20 in the third overlay region R3 at the same time. As a result, the layer 20 in the third overlay region R3 may have an inclined surface.

An overlay mark 10 may be formed on the inclined surface of the layer 20 in the third overlay region R3. This overlay mark 10 may have an inclined structure due to the inclined surface of the layer 20. Distances between the inner mark and the outer mark of the inclined overlay mark may be varied from those that would have been obtained had the overlay mark be provided on a flat surface. As a result, when an alignment between the upper and the lower patterns is inspected using the inclined overlay mark, the upper and the lower patterns may be determined to be misaligned, although the upper and the lower patterns may in fact be accurately aligned with each other. That is, the inspection of an overlay mark having an inclined structure may provide inaccurate results.

### SUMMARY

According to an example, non-limiting embodiment, a structure may be provided on an overlay region for an overlay mark. The structure may include a first pattern provided on a peripheral portion of the overlay region. The overlay region may be defined on a scribe lane of a substrate. The first pattern may project from a surface of the overlay region.

According to another example, non-limiting embodiment, a structure may be provided on an overlay region for an overlay mark. The structure may include a pattern provided on a central portion of the overlay region. The overlay region may be defined on a scribe lane of a substrate. The pattern may project from a surface of the overlay region.

According to another example, non-limiting embodiment, an overlay mark may include an inner mark provided on a scribe lane. An outer mark may be provided on the scribe lane. The outer mark may extend around a periphery of the inner mark. A structure may project from the scribe lane.

According to another example, non-limiting embodiment, a method of forming an overlay mark may involve providing a first pattern projecting from a scribe lane of a substrate. An outer mark may be provided on a portion of the scribe lane surrounded by the first pattern. An inner mark may be provided on a portion of the scribe lane surrounded by the outer mark.

According to another example, non-limiting embodiment, a semiconductor substrate may include a substrate having an active region bounded by a scribe lane. A first pattern may project from the scribe lane and extend around an inner region of the scribe lane. A second pattern may project from the inner region. An overlay mark may be provided on the inner region of the scribe lane.

### BRIEF DESCRIPTION OF THE DRAWINGS

Example, non-limiting embodiments of the invention will become readily apparent by reference to the following detailed description when considered in conjunction with the accompanying drawings wherein:

FIG. 1 is a plan view of a conventional overlay mark.

FIG. 2 is a cross sectional view taken along a line II-II′ in FIG. 1.

FIG. 3 is a plan view of a structure that may be provided on an overlay region in accordance with an example, non-limiting embodiment of the present invention.

FIG. 4 is a cross sectional view taken along a line IV-IV′ in FIG. 3.

FIG. 5 is a plan view of an overlay mark having the structure in FIGS. 3 and 4.

FIG. 6 is a cross sectional view taken along a line VI-VI′ in FIG. 5,

FIGS. 7 to 11 are cross sectional views of a method that may be implemented to form the overlay mark in FIGS. 5 and 6.

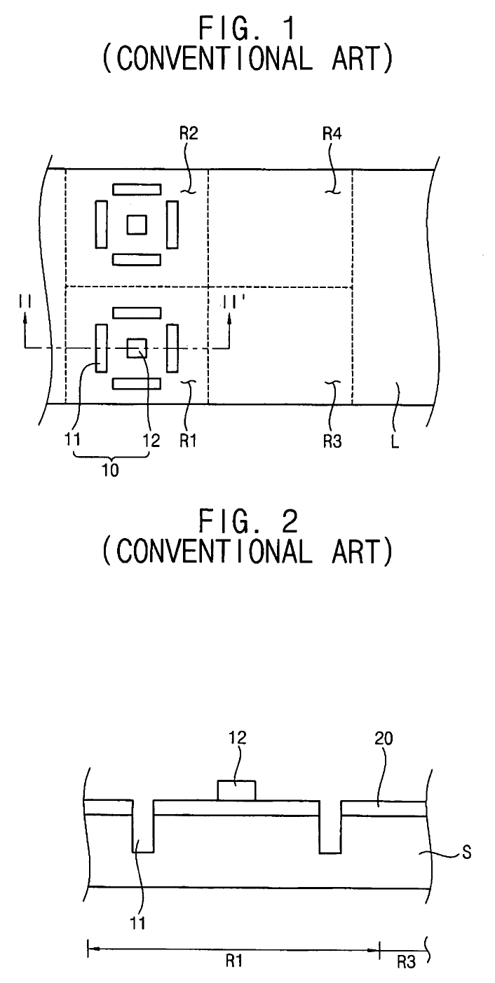

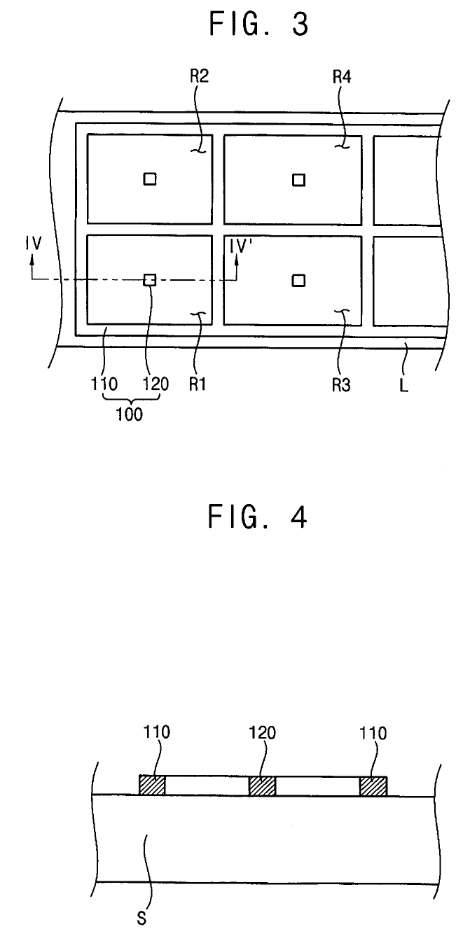

### DESCRIPTION OF EXAMPLE, NON-LIMITING EMBODIMENTS

Example, non-limiting embodiments of the present invention will be described with reference to the accompanying drawings. This invention may, however, be embodied in many different forms and should not be construed as limited to the example embodiments set forth wherein. Rather, the disclosed embodiments are provided so that this disclosure will be through and complete, and will fully convey the scope of the invention to those skilled in the art. The principles and features of this invention may be employed in varied and numerous embodiments without departing from the scope of the invention. In the drawings, the size and relative sizes of layers and regions may be exaggerated for clarity. The drawings are not to scale.

It will be understood that when an element or layer is referred to as being “on”, “connected to” and/or “coupled to” another element or layer, the element or layer may be directly on, connected and/or coupled to the other element or layer or intervening elements or layers may be present. In contrast, when an element is referred to as being “directly on,” “directly connected to” and/or “directly coupled to” another element or layer, there may be no intervening elements or layers present. Like numbers refer to like elements throughout. As used herein, the term “and/or” may include any and all combinations of one or more of the associated listed items.

It will be understood that, although the terms first, second, etc. may be used herein to describe various elements, components, regions, layers and/or sections, these elements, components, regions, layers and/or sections should not be limited by these terms. These terms may be used to distinguish one element, component, region, layer and/or section from another element, region, layer and/or section. For example, a first element, component, region, layer and/or section discussed below could be termed a second element, component, region layer and/or section without departing from the teachings of the present invention.

Spatially relative terms, such as “beneath”, “below”, “lower”, “above”, “upper” and the like, may be used to describe an element and/or feature's relationship to another element(s) and/or feature(s) as illustrated in the figures. It will be understood that the spatially relative terms are intended to encompass different orientations of the device in use and/or operation in addition to the orientation depicted in the figures. For example, if the device in the figures is turned over, elements described as “below” and/or “beneath” other elements or features would then be oriented “above” the other elements or features. The device may be otherwise oriented (rotated 90 degrees or at other orientations) and the spatially relative descriptiors used herein interpreted accordingly.

The terminology used herein is for the purpose of describing particular embodiments only and is not intended to be limiting of the invention. As used herein, the singular terms “a”, “an” and “the” are intended to include the plural forms as well, unless the context clearly indicates otherwise. It will be further understood that the terms “includes” and or “including”, when used in this specification, specify the presence of stated features, integers steps, operations, elements, and/or components, but do not preclude the presence and/or addition of one or more other features, integers, steps, operations, elements, components, and/or groups thereof.

Unless otherwise defined, all terms (including technical and scientific terms) used herein may have the same meaning as commonly understood by one of ordinary skill in the art. It will be further understood that terms, such as those defined in commonly used dictionaries, should be interpreted as having a meaning that is consistent with their meaning in the context of the relevant art and will not be interpreted in an idealized and/or overly formal sense unless expressly so defined herein.

Structure Provided on an Overlay Region

FIG. 3 is a plan view of a structure that may be provided on an overlay region in accordance with an example, non-limiting embodiment of the present invention, and FIG. 4 is a cross sectional view taken along a line IV-IV′ in FIG. 3.

Referring to FIGS. 3 and 4, a scribe lane L of a semiconductor substrate S may be divided into a plurality of overlay regions. In the present embodiment, first, second, third and fourth overlay regions R1, R2, R3 and R4 are shown. In alternative embodiments, more or less than four overlay regions may be provided. Overlay marks (not shown) may be sequentially formed in the first, second, third and fourth overlay regions R1, R2, R3 and R4, respectively, in accordance with a sequence of processes for manufacturing a semiconductor device. In alternative embodiments, overlay marks may be formed in various sequences and/or the overlay marks may be form concurrently.

A structure 100 may be provided on each of the overlay regions. The structure 100 may, for example, prevent the first, second, third and fourth overlay regions R1, R2, R3 and R4 from being damaged in a CMP process that may be implemented to manufacture the semiconductor device.

The structure 100 may include a first pattern 110 that may be provided on an outer portion of each of the first, second, third and fourth overlay regions R1, R2, R3 and R4, and a second pattern 120 that may be provided on an inner portion of each of the first, second, third and fourth overlay regions R1, R2, R3 and R4. As shown in FIG. 4, the first and the second patterns 110 and 120 may project from the overlay region of the scribe lane.

By way of example only, the first pattern 110 may be arranged along the peripheral portion of each of the first, second, third and fourth overlay regions R1, R2, R3 and R4. The first pattern 11O may have a shape that corresponds to the shape of the overlay region. Here, for example, the first pattern 110 may have a rectangular shape. The first pattern 110 may be provided continuously around the peripheral portion of each overlay region. In alternatively embodiments, the first pattern 110 may be provided discontinuously. The first pattern 110 may prevent a polishing pad used for the CMP process from making contact with the peripheral portion of each of the first, second, third and fourth overlay regions R1, R2, R3 and R4. In alternative embodiments, the first pattern 110 may have a shape that varies in accordance with a shape of the overlay mark. In alternative embodiments, the first pattern 110 may have any geometric shape.

By way of example only, the second pattern 120 may be provided on the central portion of each of the first, second, third and fourth overlay regions R1, R2, R3 and R4. The second pattern 120 may have a rectangular parallelepiped shape, for example. In alternative embodiments, the second pattern 120 may have any geometric shape. The second pattern 120 may prevent the polishing pad from making contact with the central portion of each of the first, second, third and fourth overlay regions R1, R2, R3 and R4. When the second pattern 120 is exposed through the overlay mark in an overlay measurement test, light may reflect from the exposed second pattern 120 and influence on an overlay measurement result. Thus, for example, the second pattern 120 may be covered by the overlay mark.

The first and the second patterns 110 and 120 may include (for example) an insulation material. By way of example only, the insulation material may be a silicon nitride material. The silicon nitride material may be used as an etching mask for forming a trench in an isolation process, for example, a shallow trench isolation (STI) process that may be implemented to divide the semiconductor substrate into a field region and an active region. Thus, the first and the second patterns 110 and 120 may be formed in the STI process. The first and the second patterns 110 and 120, therefore, may have heights substantially identical to each other. The first and the second patterns 110 and 120 may be fabricated from numerous and varied alternative materials and via numerous and varied alternative processes. Further, the first and the second patterns 110 and 120 of a given structure 100 may have different heights and/or be fabricated from different materials.

By virtue of the structure 100, the first, second, third and fourth overlay regions R1, R2, R3 and R4 may not have an inclined surface after (for example) the polishing pad polishes the surface of each of the first, second, third and fourth overlay regions R1, R2, R3 and R4. For example, consider a scenario in which an overlay mark may be formed in the first overlay region R1 and may not be formed in the second, third and fourth overlay regions R2, R3 and R4. Here, the structure 100 may prevent surfaces of the second, third and fourth overlay regions R2, R3 and R4 from being inclined during subsequent manufacture processes. Thus, the second, third and fourth overlay regions R2, R3 and R4 may have surfaces that facilitate more accurate overlay mark formations. As a result, the overlay measurement result may have improved reliability.

Overlay Mark

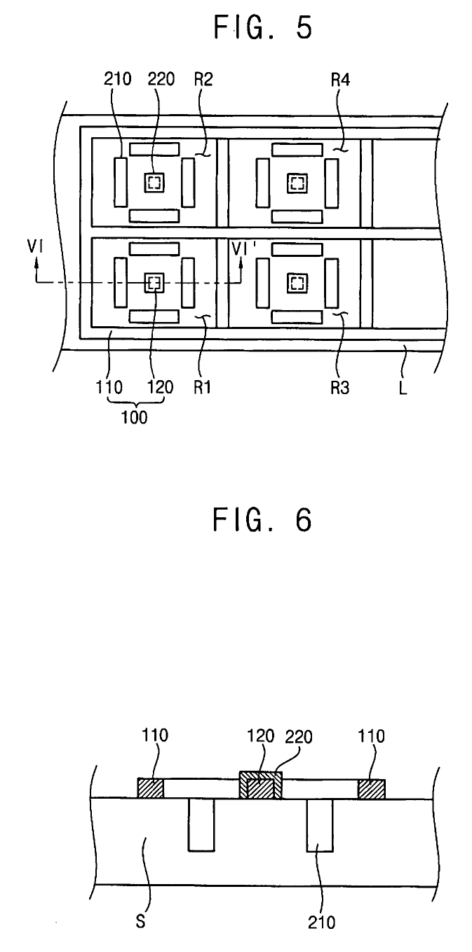

FIG. 5 is a plan view of an example overlay mark that may include the structure shown in FIGS. 3 and 4, and FIG. 6 is a cross sectional view taken along a line VI-VI′ in FIG. 5.

Referring to FIGS. 5 and 6, the overlay mark may include an outer mark 210 that may define an interior region, an inner mark 220 that may be arranged on the interior region, and the structure 100.

By way of example only, the outer mark 210 may include four trenches. Each of the trenches may have a rectangular shape. The trenches may be positioned in the overlay region to form a rectangular shape. In the present embodiment, the four trenches may be separated from each other. In alternative embodiments, the outer mark 210 may include a single continuous trench (instead of a plurality of individual and discrete trenches), more or less than four trenches, trenches that may be positioned in the overlay region to form numerous and varied geometric shapes (other than a rectangular shape), and/or trenches having numerous and varied geometric shapes (other than a rectangular shape). Further, the trenches of a given outer mark 210 may have different shapes.

The inner mark 220 may be provided on the interior region that may be defined by the outer mark 210. For example, the inner mark 220 may be provided on a central portion of each of the first, second, third and fourth overlay regions R1, R2, R3 and R4, respectively. The inner mark 220 may include a photoresist, for example.

The first pattern 110 may be provided around the outer mark 210. For example, the first pattern 110 may enclose a periphery of the outer mark 210. In the present embodiment, the first pattern 110 may have a shape corresponding to that of the outer mark 210 so that the first pattern 110 may have a rectangular shape. In alternative embodiments, the outer mark 210 and the first pattern 110 provided on a given overlay region may have different shapes. For example, the outer mark 210 may have an arcuate (e.g., circular) shape, and the first pattern 110 may have a rectangular shape.

The second pattern 120 may support the inner mark 220. The second pattern 120 may not be exposed through the inner mark 220. For example, the inner mark 220 may cover the top and the side surfaces of the second pattern 120.

According to the present embodiment, the structure 100 may protect the first, second, third and fourth overlay regions R1, R2, R3 and R4 on which the outer and the inner marks 210 and 220 may be provided. Thus, the outer and the inner marks 210 and 220 that may be provided on the first, second, third and fourth overlay regions R1, R2, R3 and R4 may have designed dimensions. As a result, the overlay measurement result may have improved reliability, for example.

Method of Forming an Overlay Mark

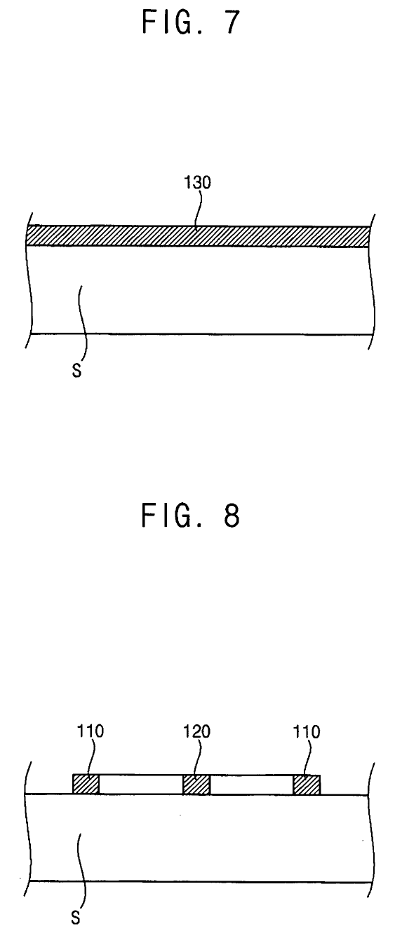

FIGS. 7 to 11 are cross sectional views of a method that may be implemented to form the overlay mark in FIGS. 5 and 6.

Referring to FIG. 7, a silicon nitride layer 130 may be provided on the scribe lane of the semiconductor substrate S. By way of example only, the silicon nitride layer 130 may be used as an etching mask to define the active region and the field region of the semiconductor substrate S. In particular, the silicon nitride layer 130 may be patterned to form a silicon nitride layer pattern (not shown). The semiconductor substrate S may be etched using the silicon nitride layer pattern as the etching mask to form a trench (not shown) at a surface portion of the semiconductor substrate S. The trench may be filled with an insulation layer (not shown) to divide the semiconductor substrate S into the active region and the field region.

Referring to FIG. 8, the first and the second patterns 10 and 120 may be formed on the scribe lane of the semiconductor substrate S via patterning the silicon nitride layer 130. Numerous and varied patterning techniques that are well known in this art may be suitably implemented. The first pattern 110 may be formed on the peripheral portion of the overlay region. The second pattern 120 may be formed on the central portion of the overlay region.

An active structure (not shown) may be formed on the active region of the semiconductor substrate S. Example processes for forming the active structure may include (among other things) a process for forming an insulation interlayer (not shown) and a conductive layer (not shown) on the semiconductor substrate S, a CMP process for planarizing the insulation interlayer and the conductive layer, etc. An example CMP apparatus that may be used to carry out the CMP process may include a platen for holding the semiconductor substrate S, a polishing pad, and a slurry line for providing slurry to the polishing pad. The semiconductor substrate S held by the platen may contact the polishing pad. The semiconductor substrate S may be polished with the platen and the polishing pad being rotated in opposite directions.

In the CMP process, the polishing pad may contact the first and/or the second patterns 110 and 120 provided on an overlay region, for example, the first overlay region R1 where the overlay mark may be formed, and the second overlay region R2 where the overlay mark may not be formed. The first and/or the second patterns 110 and 120 may prevent the polishing pad from contacting the surfaces of the overlay regions. In this way, the polishing pad may not create a step difference between the surfaces of the first and the second overlay regions R1 and R2 so that the second overlay region R2 may not have an inclined surface. Accordingly, the desired profile of the surface of the second overlay region R2 may be maintained.

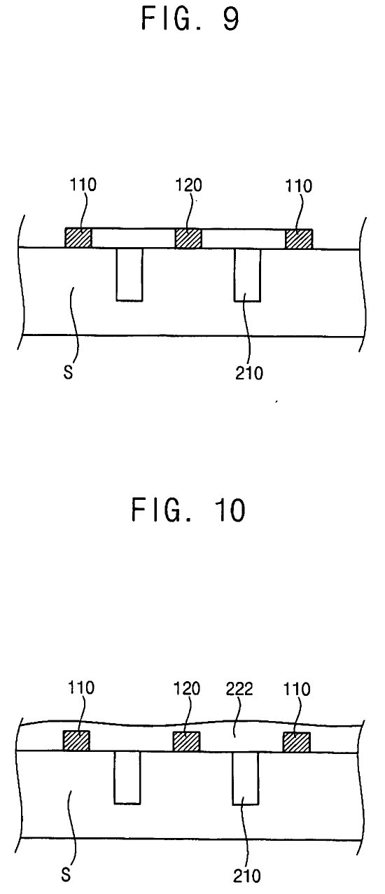

Referring to FIG. 9, a photoresist pattern (not shown) may be formed on the second overlay region R2. The second overlay region R2 may be partially etched using the photoresist pattern as an etching mask to form the trenches of the outer mark 210. By way of example only, the outer mark 210 may be positioned on an interior area of the scribe lane that may be defined by the first pattern 110. The outer mark 210 may be provided on an area of the scribe lane between the first pattern 110 and the second pattern 120. For example, the outer mark 210 may extend around a periphery of the second pattern 120, and the first pattern 110 may extend around a periphery of the outer mark 210.

Referring to FIG. 10, a photoresist film 222, may be formed on the second overlay region R2. The photoresist film 222 may cover the first and the second patterns 110 and 120.

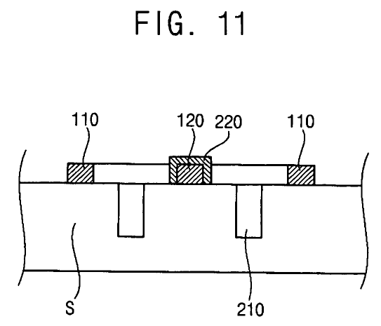

Referring to FIG 11, the photoresist film 222 may be exposed and developed to form the inner mark 220. The inner mark 220 may cover the second protection pattern 120.

In the present embodiment, the outer mark 210 may correspond to the trenches and the inner mark 220 may correspond to the photoresist pattern. In alternative embodiments, overlay marks having other configurations may be formed in the overlay regions. For example, the outer mark may correspond to projection features (as opposed to recessed features, such as trenches).

Having described example, non-limiting embodiments of the present invention, numerous modifications and variations may become apparent to persons skilled in the art. It is to be understood that changes may be made to the example, non-limiting embodiments of the present invention, and that such changes may fall within the spirit and scope of the invention defined by the appended claims.

What is claimed is:

1. A structure provided on an overlay region for an overlay mark, the structure comprising:
a first pattern provided on a peripheral portion of the overlay region, which is defined on a scribe lane of a substrate, the first pattern projecting from a surface of the overlay region.

2. The structure of claim 1, wherein the first pattern encloses a periphery of the overlay mark in the overlay region.

3. The structure of claim 2, wherein the first pattern has a rectangular shape.

4. The structure of claim 1, wherein the first pattern comprises an insulation material.

5. The structure of claim 4, wherein the insulation material comprises silicon nitride.

6. The structure of claim 1, further comprising a second pattern provided on a central portion of the overlay region, the second pattern projecting from a surface of the overlay region.

7. The structure of claim 6, wherein the second pattern is covered by the overlay mark.

8. The structure of claim 6, wherein the second pattern comprises an insulation material.

9. The structure of claim 8, wherein the insulation material comprises silicon nitride.

10. A structure provided on an overlay region for an overlay mark, comprising;
a pattern provided on a central portion of the overlay region, which is defined on a scribe lane of a substrate, the pattern projecting from a surface of the overlay region.

11. The structure of claim 10, wherein the pattern is covered by the overlay mark.

12. The structure of claim 10, wherein the pattern comprises an insulation material.

13. The structure of claim 12, wherein the insulation material comprises silicon nitride.

14. An overlay mark comprising:
an inner mark provided on a scribe lane;
an outer mark provided on the scribe lane, the outer mark extending around a periphery of the inner mark; and
a structure projecting from the scribe lane.

15. The overlay mark of claim 14, wherein the outer mark comprises trenches formed in the scribe lane.

16. The overlay mark of claim 15, wherein the trenches are arranged in a rectangular shape.

17. The overlay mark of claim 14, wherein the inner mark comprises a photoresist pattern provided on the scribe lane.

18. The overlay mark of claim 14, wherein the structure comprises a first pattern surrounding a periphery of the outer mark.

19. The overlay mark of claim 18, wherein the structure further comprises a second pattern supporting the inner mark.

20. A method of forming an overlay mark, comprising:
providing a first pattern projecting from a scribe lane of a substrate;
providing an outer mark on a portion of the scribe lane surrounded by the first pattern; and
providing an inner mark on a portion of the scribe lane surrounded by the outer mark.

21. The method of claim 20, further comprising providing a second pattern on the portion of the scribe lane surrounded by the first pattern, wherein providing the inner mark includes covering the second pattern with the inner mark.

22. The method of claim 20, wherein the second pattern is simultaneously formed with the first pattern.

23. The method of claim 22, wherein the first and the second patterns are formed simultaneously with an isolation process for dividing the substrate into an active region and a field region.

24. The method of claim 20, wherein forming the outer mark comprises forming trenches in the scribe lane.

25. The method of claim 20, wherein forming the inner mark comprises:
forming a photoresist film on the scribe lane; and
patterning the photoresist film.

26. A semiconductor substrate comprising:
a substrate having an active region bounded by a scribe lane;
a first pattern projecting from the scribe lane and extending around an inner region of the scribe lane;
a second pattern projecting from the inner region; and
an overlay mark provided on the inner region of the scribe lane.

27. The semiconductor substrate of claim 26, wherein the first pattern extends continuously around the inner region of the scribe lane.

28. The semiconductor substrate of claim 26, wherein the first pattern extends discontinuously around the inner region of the scribe lane.

29. The semiconductor substrate of claim 26, wherein the overlay mark comprises:
an outer mark provided between the first pattern and the second pattern; and
an inner mark provided on the second pattern.
